(19) United States
(12) Patent Application Publication
(10) Pub. No.: US 2025/0040190 A1
(43) Pub. Date: Jan. 30, 2025

(54) SEMICONDUCTOR STRUCTURE

(71) Applicant: Powerchip Semiconductor Manufacturing Corporation, Hsinchu (TW)

(72) Inventors: Shou-Zen Chang, Hsinchu City (TW); Yu-Chang Lin, Hsinchu (TW); Min-Cheng Chen, Hsinchu County (TW)

(73) Assignee: Powerchip Semiconductor Manufacturing Corporation, Hsinchu (TW)

(21) Appl. No.: 18/523,924

(22) Filed: Nov. 30, 2023

(30) Foreign Application Priority Data
Jul. 24, 2023 (TW) 112127645

(51) Int. Cl. H01L 29/786; H01L 23/498; H01L 29/94

(52) U.S. Cl. CPC H01L 29/7869; H01L 23/49827; H01L 29/945

(57) ABSTRACT

A semiconductor structure including a substrate, a capacitor, and an oxide semiconductor field effect transistor (OSFET). The capacitor is located on the substrate. The oxide semiconductor field effect transistor is located on the substrate. The oxide semiconductor field effect transistor is electrically connected to the capacitor.

### CROSS-REFERENCE TO RELATED APPLICATION

This application claims the priority benefit of Taiwan application serial no. 112127645, filed on Jul. 24, 2023. The entirety of the above-mentioned patent application is hereby incorporated by reference herein and made a part of this specification.

### BACKGROUND

### Technical Field

The invention relates to a semiconductor structure, and particularly relates to a semiconductor structure including a capacitor.

### Description of Related Art

Currently, the integrated capacitor that can be integrated with other semiconductor devices (e.g., complementary metal oxide semiconductor (CMOS) device) has been developed. However, the current integrated capacitor has the large leakage current and cannot withstand the high operating voltage. Therefore, how to effectively reduce the leakage current of the integrated capacitor and increase the operating voltage of the integrated capacitor is the goal of continuous efforts.

### SUMMARY

The invention provides a semiconductor structure, which can effectively reduce the leakage current of the capacitor and increase the operating voltage of the capacitor.

The invention provides a semiconductor structure, which includes a substrate, a capacitor, and an oxide semiconductor field effect transistor (OSFET). The capacitor is located on the substrate. The oxide semiconductor field effect transistor is located on the substrate. The oxide semiconductor field effect transistor is electrically connected to the capacitor.

According to an embodiment of the invention, in the semiconductor structure, the capacitor may be a trench capacitor.

According to an embodiment of the invention, in the semiconductor structure, the capacitor may be a parallel-plate capacitor.

According to an embodiment of the invention, in the semiconductor structure, the oxide semiconductor field effect transistor may be an oxide semiconductor thin film transistor (OSTFT).

According to an embodiment of the invention, in the semiconductor structure, the oxide semiconductor field effect transistor may be located above the capacitor.

According to an embodiment of the invention, in the semiconductor structure, the oxide semiconductor field effect transistor may be located below the capacitor.

According to an embodiment of the invention, in the semiconductor structure, the oxide semiconductor field effect transistor may be located on one side of the capacitor.

According to an embodiment of the invention, in the semiconductor structure, the oxide semiconductor field effect transistor may include a first electrode layer, a first dielectric layer, a channel layer, a second electrode layer, and a third electrode layer. The first electrode layer is located on the substrate. The first dielectric layer is located on the first electrode layer. The channel layer is located on the first dielectric layer and is located above the first electrode layer. The second electrode layer and third electrode layer are located on the first dielectric layer and are located on two sides of the channel layer.

According to an embodiment of the invention, in the semiconductor structure, the material of the first electrode layer is, for example, molybdenum, titanium, tantalum, tungsten, aluminum, copper, chromium, or an alloy thereof.

According to an embodiment of the invention, in the semiconductor structure, the material of the first dielectric layer is, for example, silicon oxide, silicon nitride, or hafnium nitride.

According to an embodiment of the invention, in the semiconductor structure, the material of the channel layer may be an oxide semiconductor. The oxide semiconductors may include indium gallium zinc oxide (IGZO), zinc oxide (ZnO), indium zinc oxide (IZO), cobalt oxide (CoOₓ), nickel oxide (NiOₓ), strontium copper oxide (SrCu₂Oₓ), copper aluminum oxide (CuAlO₂), copper indium oxide (CuInO₂), or copper gallium oxide (CuGaO₂).

According to an embodiment of the invention, in the semiconductor structure, the material of the second electrode layer and the material of the third electrode layer may be an N-type oxide semiconductor. The N-type oxide semiconductor may include indium gallium zinc oxide (IGZO), zinc oxide (ZnO), or indium zinc oxide (IZO), and the N-type oxide semiconductor may have an N-type dopant.

According to an embodiment of the invention, in the semiconductor structure, the material of the second electrode layer and the material of the third electrode layer may be a P-type oxide semiconductor. The P-type oxide semiconductor may include cobalt oxide (CoOₓ), nickel oxide (NiOₓ), strontium copper oxide (SrCu₂Oₓ), copper aluminum oxide (CuAlO₂), copper indium oxide (CuInO₂), or copper gallium oxide (CuGaO₂), and the P-type oxide semiconductor may have a P-type dopant.

According to an embodiment of the invention, in the semiconductor structure, the capacitor may be located in the substrate. The capacitor may include a fourth electrode layer, a fifth electrode layer, a second dielectric layer, and a third dielectric layer. The fourth electrode layer is located in the substrate. The fifth electrode layer is located on the fourth electrode layer. The second dielectric layer is located between the fourth electrode layer and the substrate. The third dielectric layer is located between the fourth electrode layer and the fifth electrode layer.

According to an embodiment of the invention, in the semiconductor structure, the second electrode layer may be electrically connected to the fourth electrode layer.

According to an embodiment of the invention, in the semiconductor structure, the second electrode layer may be electrically connected to the fifth electrode layer.

According to an embodiment of the invention, the semiconductor structure may further include a dielectric layer structure. The dielectric layer structure is located on the substrate. The capacitor and the oxide semiconductor field effect transistor may be located in the dielectric layer structure. The capacitor may include a fourth electrode layer, a fifth electrode layer, and a second dielectric layer. The fourth electrode layer is located in the dielectric layer structure. The fifth electrode layer is located on the fourth electrode layer. The second dielectric layer is located between the fourth electrode layer and the fifth electrode layer.

According to an embodiment of the invention, in the semiconductor structure, the second electrode layer may be electrically connected to the fourth electrode layer.

According to an embodiment of the invention, in the semiconductor structure, the second electrode layer may be electrically connected to the fifth electrode layer.

According to an embodiment of the invention, the semiconductor structure may further include a through-substrate via (TSV). The TSV is located in the substrate. The TSV may pass through the substrate.

Based on the above description, in the semiconductor structure according to the invention, since the oxide semiconductor field effect transistor is electrically connected to the capacitor, the leakage current of the capacitor can be effectively reduced and the operating voltage of the capacitor can be increased.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a semiconductor structure according to some embodiments of the invention.

FIG. 2 is a cross-sectional view of a semiconductor structure according to other embodiments of the invention.

FIG. 3 is a cross-sectional view of a semiconductor structure according to other embodiments of the invention.

FIG. 4 is a cross-sectional view of a semiconductor structure according to other embodiments of the invention.

FIG. 5 is a cross-sectional view of a semiconductor structure according to other embodiments of the invention.

FIG. 6 is a cross-sectional view of a semiconductor structure according to other embodiments of the invention.

FIG. 7 is a cross-sectional view of a semiconductor structure according to other embodiments of the invention.

FIG. 8 is a cross-sectional view of a semiconductor structure according to other embodiments of the invention.

FIG. 9 is a cross-sectional view of a semiconductor structure according to other embodiments of the invention.

FIG. 10 is a cross-sectional view of a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

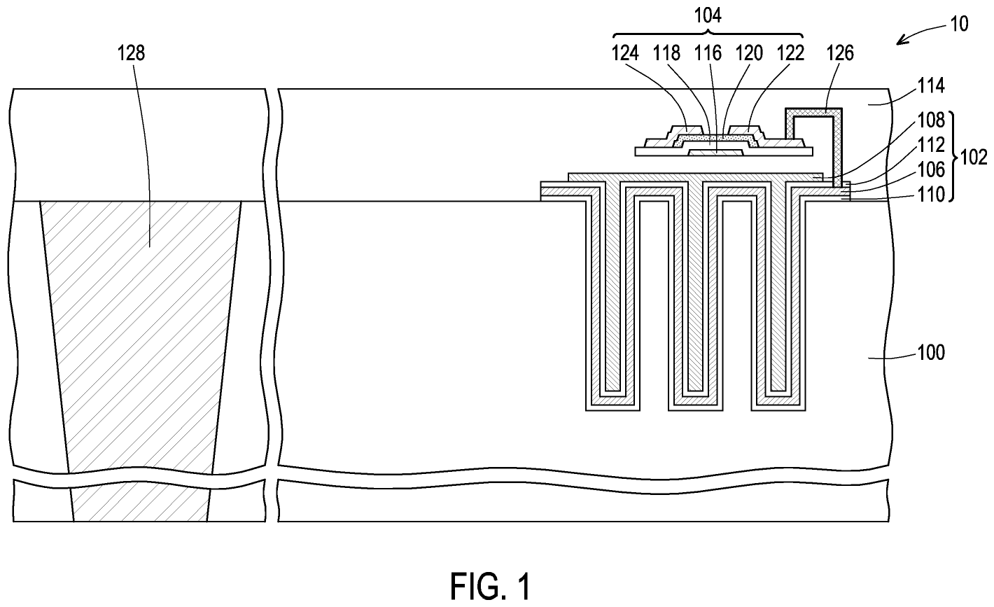

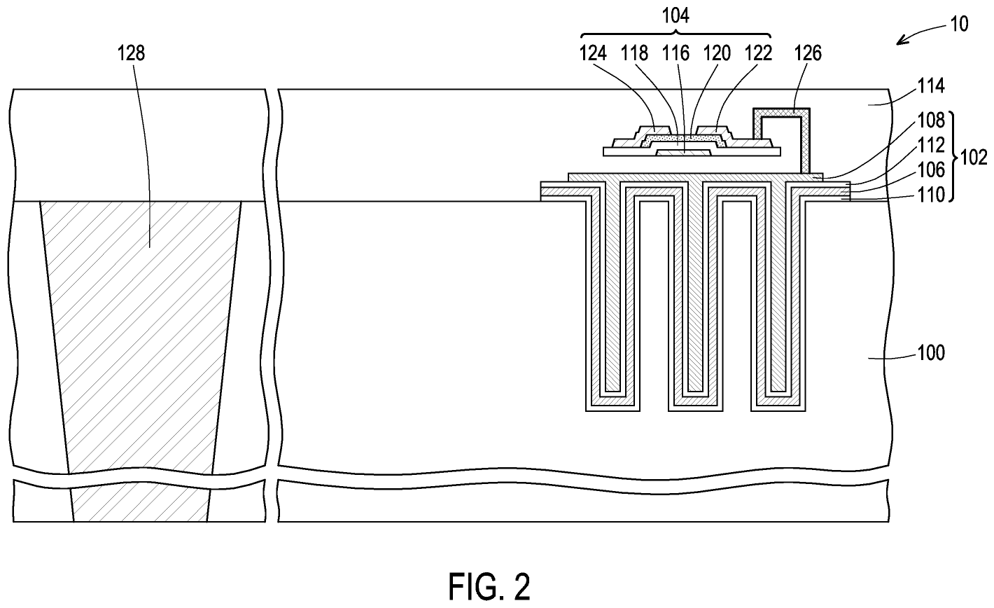

FIG. 1 is a cross-sectional view of a semiconductor structure according to some embodiments of the invention. FIG. 2 is a cross-sectional view of a semiconductor structure according to other embodiments of the invention.

Referring to FIG. 1A, a semiconductor structure 10 includes a substrate 100, a capacitor 102, and an oxide semiconductor field effect transistor 104. In some embodiments, the substrate 100 may be a semiconductor substrate such as a silicon substrate.

The capacitor 102 is located on the substrate 100. In some embodiments, the capacitor 102 may be an integrated capacitor. In the present embodiment, the capacitor 102 may be a trench capacitor. In some embodiments, the capacitor 102 may be located in the substrate 100. In some embodiments, the capacitor 102 may include an electrode layer 106, an electrode layer 108, a dielectric layer 110, and a dielectric layer 112. The electrode layer 106 is located in the substrate 100. A portion of the electrode layer 106 may be located above the top surface of the substrate 100. In some embodiments, the material of the electrode layer 106 is, for example, doped polysilicon. The electrode layer 108 is located on the electrode layer 106. A portion of the electrode layer 108 may be located above the top surface of the substrate 100. In some embodiments, the material of the electrode layer 108 is, for example, doped polysilicon. The dielectric layer 110 is located between the electrode layer 106 and the substrate 100. In some embodiments, the material of the dielectric layer 110 is, for example, silicon oxide. The dielectric layer 112 is located between the electrode layer 106 and the electrode layer 108. In some embodiments, the material of the dielectric layer 112 is, for example, silicon oxide or a high dielectric constant (high-k) dielectric material.

The semiconductor structure 10 may further include a dielectric layer structure 114. The dielectric layer structure 114 is located on the substrate 100. The dielectric layer structure 114 may cover the capacitor 102. In some embodiments, the dielectric layer structure 114 may be a multilayer structure. In some embodiments, the material of the dielectric layer structure 114 is, for example, silicon oxide, silicon nitride, or a combination thereof.

The oxide semiconductor field effect transistor 104 is located on the substrate 100. In the present embodiment, the oxide semiconductor field effect transistor 104 may be located above the capacitor 102, thereby effectively reducing the area of the semiconductor structure 10. In some embodiments, the oxide semiconductor field effect transistor 104 may be located in the dielectric layer structure 114. In some embodiments, the oxide semiconductor field effect transistor 104 may be an oxide semiconductor thin film transistor.

In some embodiments, the oxide semiconductor field effect transistor 104 may include an electrode layer 116, a dielectric layer 118, a channel layer 120, an electrode layer 122, and an electrode layer 124. The electrode layer 116 is located on the substrate 100. In some embodiments, the electrode layer 116 may be used as a gate. In some embodiments, the electrode layer 116 may be located in the dielectric layer structure 114 above the capacitor 102. In some embodiments, the material of the electrode layer 116 is, for example, molybdenum, titanium, tantalum, tungsten, aluminum, copper, chromium, or an alloy thereof.

The dielectric layer 118 is located on the electrode layer 116. In some embodiments, the dielectric layer 118 may be used as a gate dielectric layer. In some embodiments, the material of the dielectric layer 118 is, for example, silicon oxide, silicon nitride, or hafnium nitride.

The channel layer 120 is located on the dielectric layer 118 and is located above the electrode layer 116. In some embodiments, the material of the channel layer 120 may be an oxide semiconductor. In some embodiments, the oxide semiconductor may include indium gallium zinc oxide (IGZO), zinc oxide (ZnO), indium zinc oxide (IZO), cobalt oxide (CoOₓ), nickel oxide (NiOₓ), strontium copper oxide (SrCu₂Oₓ), copper aluminum oxide (CuAlO₂), copper indium oxide (CuInO₂), or copper gallium oxide (CuGaO₂).

The electrode layer 122 and the electrode layer 124 are located on the dielectric layer 118 and are located on two sides of the channel layer 120. In some embodiments, the electrode layer 122 and the electrode layer 124 may partially cover the channel layer 120. The electrode layer 122 and the electrode layer 124 may be used as one and the other of a source and a drain, respectively. In the present embodiment, the electrode layer 122 may be used as a drain, and the electrode layer 124 may be used as a source. The material of the electrode layer 122 and the material of the electrode layer 124 may be an N-type oxide semiconductor or a P-type oxide semiconductor. In some embodiments, the N-type oxide semiconductor may include indium gallium zinc oxide (IGZO), zinc oxide (ZnO), or indium zinc oxide (IZO), and the N-type oxide semiconductor may have an N-type dopant. In some embodiments, the P-type oxide semiconductor may include cobalt oxide (CoOₓ), nickel oxide (NiOₓ), strontium copper oxide (SrCu₂Oₓ), copper aluminum oxide (CuAlO₂), copper indium oxide (CuInO₂), or copper gallium oxide (CuGaO₂), and the P-type oxide semiconductor may have a P-type dopant.

The oxide semiconductor field effect transistor 104 is electrically connected to the capacitor 102. In the present embodiment, as shown in FIG. 1, the electrode layer 122 may be electrically connected to the electrode layer 106, but the invention is not limited thereto. In other embodiments, as shown in FIG. 2, the electrode layer 122 may be electrically connected to the electrode layer 108.

In some embodiments, the semiconductor structure 10 may further include an interconnect structure 126. The interconnect structure 126 is located in the dielectric layer structure 114. In the present embodiment, as shown in FIG. 1, the electrode layer 122 may be electrically connected to the electrode layer 106 by the interconnect structure 126. In other embodiments, as shown in FIG. 2, the electrode layer 122 may be electrically connected to the electrode layer 108 by the interconnect structure 126. In some embodiments, the interconnect structure 126 may include a contact, a conductive line, or a combination thereof. In some embodiments, the material of the interconnect structure 126 is, for example, tungsten, aluminum, copper, titanium, titanium nitride, tantalum, tantalum nitride, or a combination thereof.

In some embodiments, the semiconductor structure 10 may further include a TSV 128. The TSV 128 is located in the substrate 100. The TSV 128 may pass through the substrate 100. In some embodiments, the material of the TSV 128 is, for example, copper, tantalum, tantalum nitride, or a combination thereof.

In addition, although not shown in the figure, there may be other required components (e.g., semiconductor devices, interconnect structures and/or dielectric layers) on the substrate 100, in the substrate 100, and in the dielectric layer structure 114, and the description thereof is omitted here. Furthermore, in FIG. 1 and FIG. 2, the same or similar components are denoted by the same reference symbols, and the description thereof is omitted.

Based on the above embodiments, in the semiconductor structure 10, since the oxide semiconductor field effect transistor 104 is electrically connected to the capacitor 102, the leakage current of the capacitor 102 can be effectively reduced and the operating voltage of the capacitor 102 can be increased.

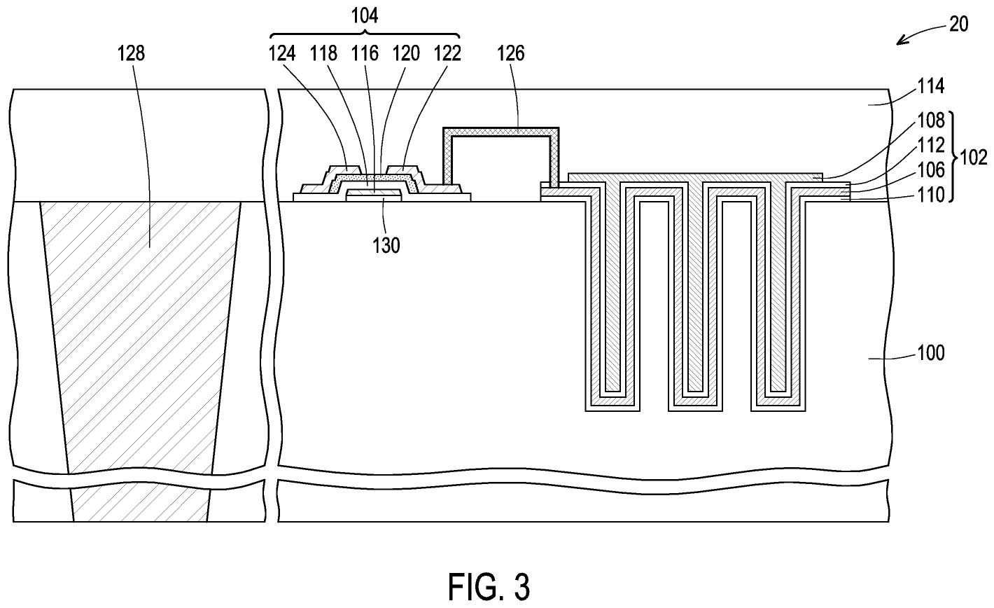

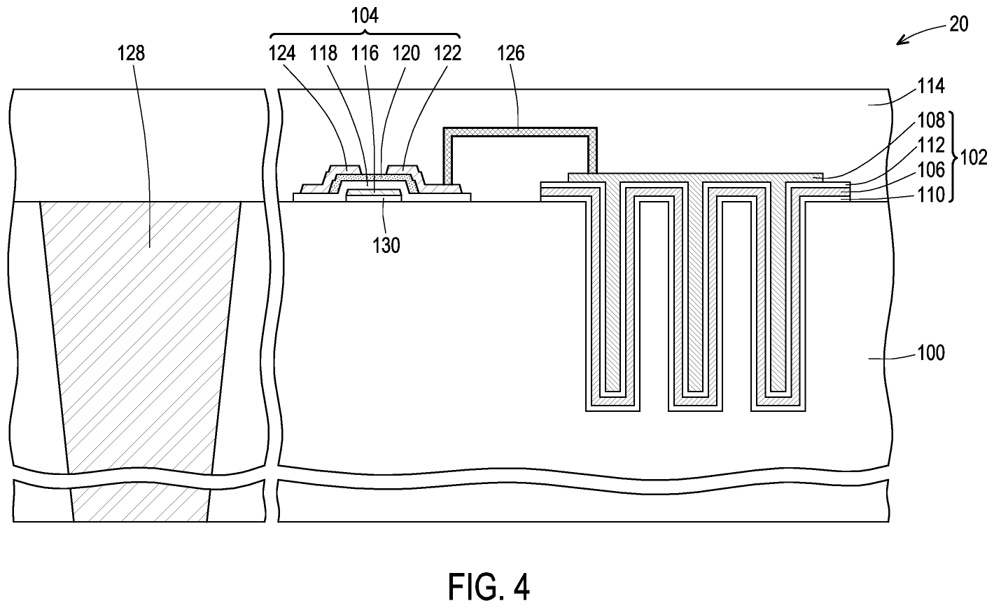

FIG. 3 is a cross-sectional view of a semiconductor structure according to other embodiments of the invention. FIG. 4 is a cross-sectional view of a semiconductor structure according to other embodiments of the invention.

Referring to FIG. 1 and FIG. 3, the difference between the semiconductor structure 20 of FIG. 3 and the semiconductor structure 10 of FIG. 1 is as follows. In the semiconductor structure 20 of FIG. 3, the oxide semiconductor field effect transistor 104 may be located on one side of the capacitor 102. In addition, the semiconductor structure 20 may further include a dielectric layer 130. The dielectric layer 130 is located between the electrode layer 116 and the substrate 100. In some embodiments, the material of the dielectric layer 130 is, for example, silicon oxide.

In the semiconductor structure 20 of FIG. 3, the electrode layer 122 may be electrically connected to the electrode layer 106, but the invention is not limited thereto. For example, in the semiconductor structure 20 of FIG. 3, the electrode layer 122 may be electrically connected to the electrode layer 106 by the interconnect structure 126. In other embodiments, as shown in FIG. 4, the electrode layer 122 may be electrically connected to the electrode layer 108. For example, as shown in FIG. 4, the electrode layer 122 may be electrically connected to the electrode layer 108 by the interconnect structure 126.

In addition, in FIG. 1, FIG. 3, and FIG. 4, the same or similar components are denoted by the same reference symbols, and the description thereof is omitted.

Based on the above embodiments, in the semiconductor structure 20, since the oxide semiconductor field effect transistor 104 is electrically connected to the capacitor 102, the leakage current of the capacitor 102 can be effectively reduced and the operating voltage of the capacitor 102 can be increased.

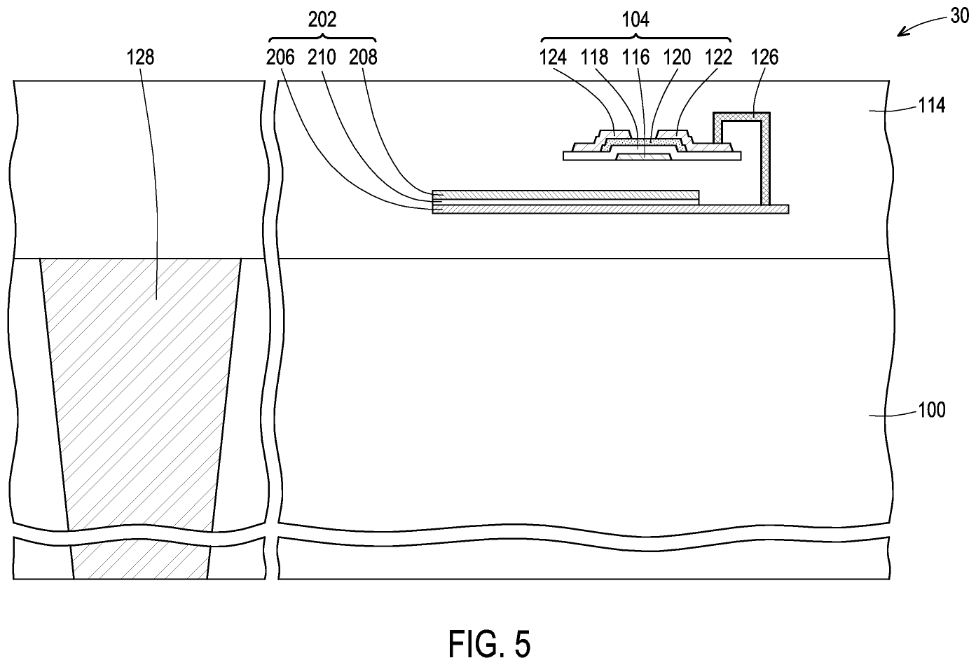

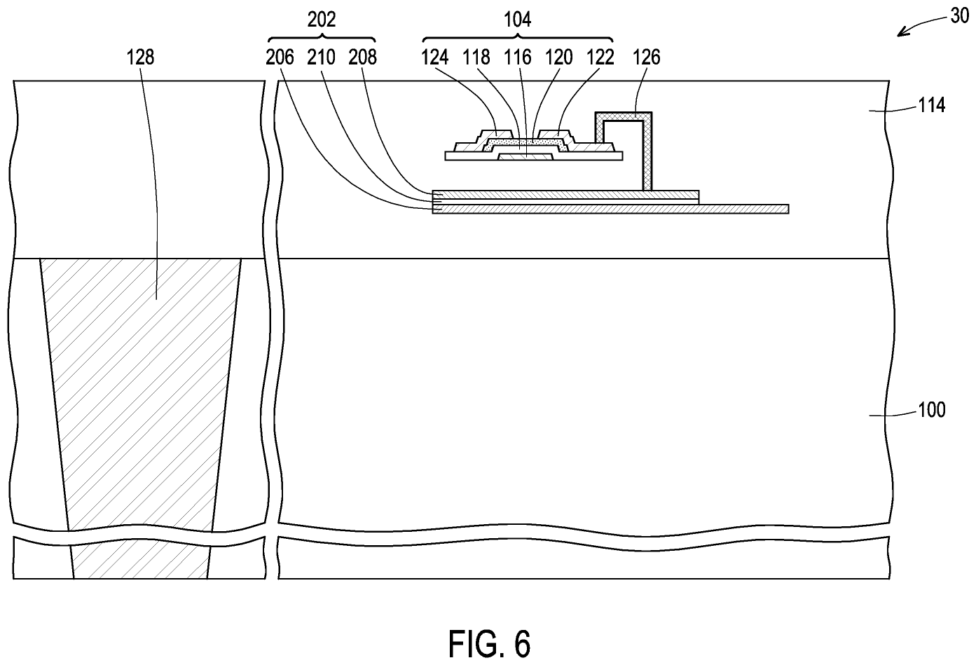

FIG. 5 is a cross-sectional view of a semiconductor structure according to other embodiments of the invention. FIG. 6 is a cross-sectional view of a semiconductor structure according to other embodiments of the invention.

Referring to FIG. 1 and FIG. 5, the difference between the semiconductor structure 30 of FIG. 5 and the semiconductor structure 10 of FIG. 1 is as follows. The capacitor 202 in the semiconductor structure 30 is different from the capacitor 102 in the semiconductor structure 10. In the semiconductor structure 30, the capacitor 202 may be a parallel-plate capacitor.

In the semiconductor structure 30, the capacitor 202 and the oxide semiconductor field effect transistor 104 may be located in the dielectric layer structure 114. The oxide semiconductor field effect transistor 104 may be located above the capacitor 202, thereby effectively reducing the area of the semiconductor structure 30. In some embodiments, the capacitor 202 may include an electrode layer 206, an electrode layer 208, and a dielectric layer 210. The electrode layer 206 is located in the dielectric layer structure 114. In some embodiments, the material of the electrode layer 206 is, for example, tantalum, tantalum nitride, or a combination thereof. The electrode layer 208 is located on the electrode layer 206. In some embodiments, the material of the electrode layer 208 is, for example, tantalum, tantalum nitride, or a combination thereof. The dielectric layer 210 is located between the electrode layer 206 and the electrode layer 208. In some embodiments, the material of the dielectric layer 210 is, for example, silicon nitride or a high dielectric constant (high-k) dielectric material. In some embodiments, the high-k dielectric material is, for example, aluminum oxide (Al₂O₃), zirconium oxide (ZrO₂), or tantalum oxide (Ta₂O₅).

In the semiconductor structure 30 of FIG. 5, the electrode layer 122 may be electrically connected to the electrode layer 206, but the invention is not limited thereto. For example, in the semiconductor structure 30 of FIG. 5, the electrode layer 122 may be electrically connected to the electrode layer 206 by the interconnect structure 126. In other embodiments, as shown in FIG. 6, the electrode layer 122 may be electrically connected to the electrode layer 208. For example, as shown in FIG. 6, the electrode layer 122 may be electrically connected to the electrode layer 208 by the interconnect structure 126.

In addition, in FIG. 1, FIG. 5, and FIG. 6, the same or similar components are denoted by the same reference symbols, and the description thereof is omitted.

Based on the above embodiments, in the semiconductor structure 30, since the oxide semiconductor field effect transistor 104 is electrically connected to the capacitor 202, the leakage current of the capacitor 202 can be effectively reduced and the operating voltage of the capacitor 202 can be increased.

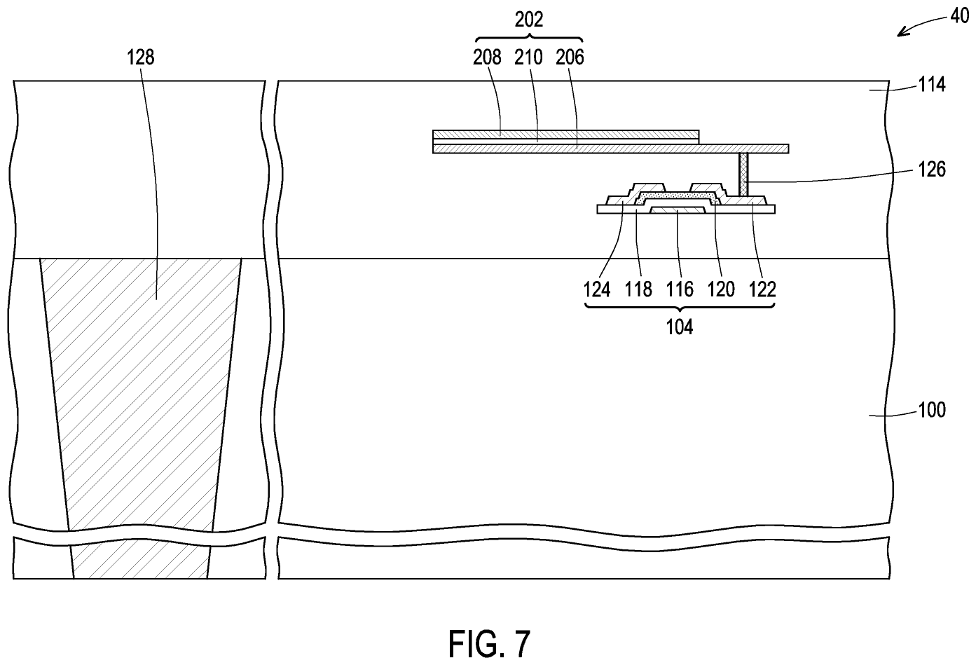

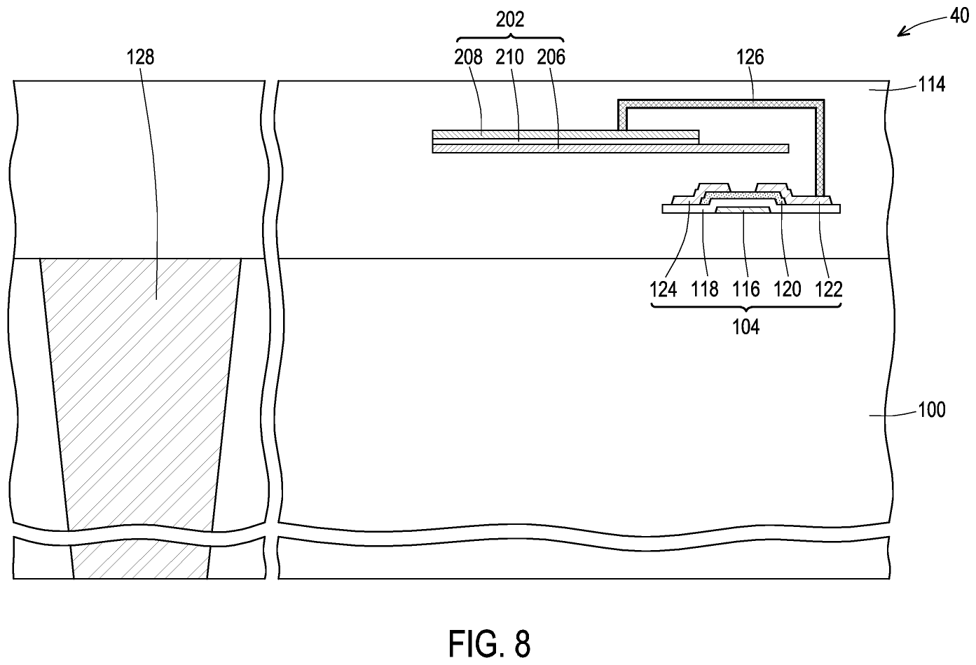

FIG. 7 is a cross-sectional view of a semiconductor structure according to other embodiments of the invention. FIG. 8 is a cross-sectional view of a semiconductor structure according to other embodiments of the invention.

Referring to FIG. 7 and FIG. 5, the difference between the semiconductor structure 40 of FIG. 7 and the semiconductor structure 30 of FIG. 5 is as follows. In the semiconductor structure 40 of FIG. 7, the oxide semiconductor field effect transistor 104 may be located below the capacitor 202, thereby effectively reducing the area of the semiconductor structure 40.

In the semiconductor structure 40 of FIG. 7, the electrode layer 122 may be electrically connected to the electrode layer 206, but the invention is not limited thereto. For example, in the semiconductor structure 40 of FIG. 7, the electrode layer 122 may be electrically connected to the electrode layer 206 by the interconnect structure 126. In other embodiments, as shown in FIG. 8, the electrode layer 122 may be electrically connected to the electrode layer 208. For example, as shown in FIG. 8, the electrode layer 122 may be electrically connected to the electrode layer 208 by the interconnect structure 126.

In addition, in FIG. 5, FIG. 7, and FIG. 8, the same or similar components are denoted by the same reference symbols, and the description thereof is omitted.

Based on the above embodiments, in the semiconductor structure 40, since the oxide semiconductor field effect transistor 104 is electrically connected to the capacitor 202, the leakage current of the capacitor 202 can be effectively reduced and the operating voltage of the capacitor 202 can be increased.

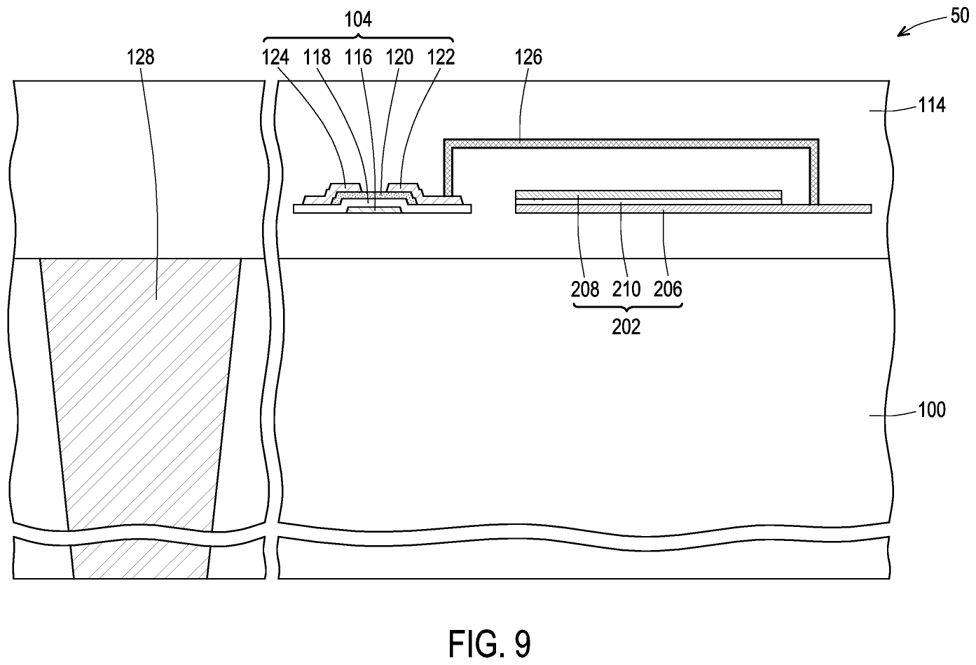

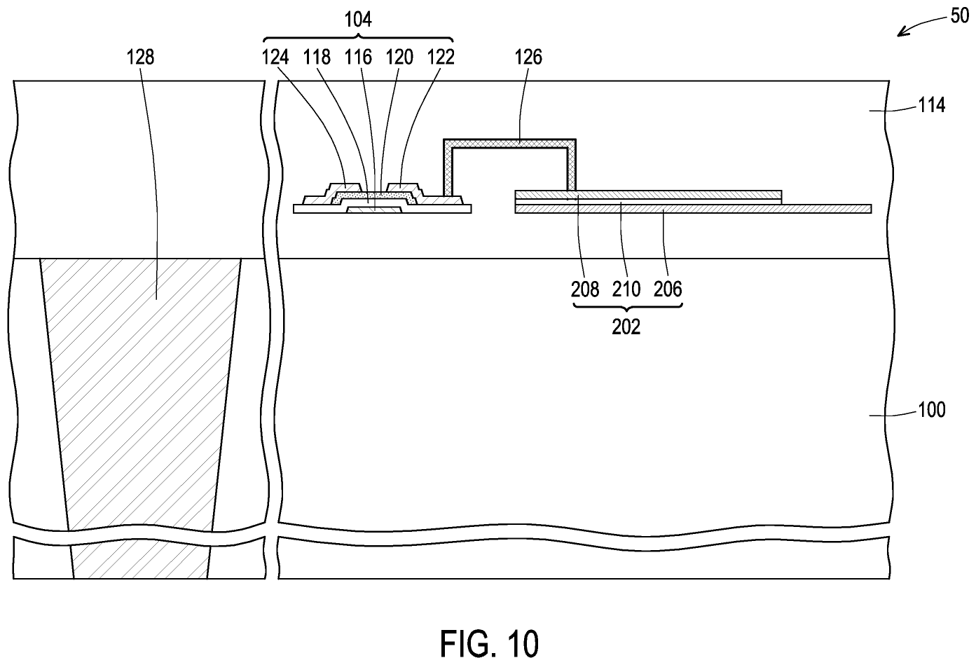

FIG. 9 is a cross-sectional view of a semiconductor structure according to other embodiments of the invention. FIG. 10 is a cross-sectional view of a semiconductor structure according to other embodiments of the invention.

Please refer to FIG. 9 and FIG. 5, the difference between the semiconductor structure 50 of FIG. 9 and the semiconductor structure 30 of FIG. 5 is as follows. In the semiconductor structure 50 of FIG. 9, the oxide semiconductor field effect transistor 104 may be located on one side of the capacitor 202.

In the semiconductor structure 50 of FIG. 9, the electrode layer 122 may be electrically connected to the electrode layer 206, but the invention is not limited thereto. For example, in the semiconductor structure 50 of FIG. 9, the electrode layer 122 may be electrically connected to the electrode layer 206 by the interconnect structure 126. In other embodiments, as shown in FIG. 10, the electrode layer 122 may be electrically connected to the electrode layer 208. For example, as shown in FIG. 10, the electrode layer 122 may be electrically connected to the electrode layer 208 by the interconnect structure 126.

In addition, in FIG. 5, FIG. 9 and FIG. 10, the same or similar components are denoted by the same reference symbols, and the description thereof is omitted.

Based on the above embodiments, in the semiconductor structure 50, since the oxide semiconductor field effect transistor 104 is electrically connected to the capacitor 202, the leakage current of the capacitor 202 can be effectively reduced and the operating voltage of the capacitor 202 can be increased.

In summary, the semiconductor structure of the aforementioned embodiments includes a capacitor and an oxide semiconductor field effect transistor, and the oxide semiconductor field effect transistor is electrically connected to the capacitor, thereby effectively reducing the leakage current of the capacitor and increasing the operating voltage of the capacitor.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate;
a capacitor located on the substrate; and
an oxide semiconductor field effect transistor located on the substrate and electrically connected to the capacitor.

2. The semiconductor structure according to claim 1, wherein the capacitor comprises a trench capacitor.

3. The semiconductor structure according to claim 1, wherein the capacitor comprises a parallel-plate capacitor.

4. The semiconductor structure according to claim 1, wherein the oxide semiconductor field effect transistor comprises an oxide semiconductor thin film transistor.

5. The semiconductor structure according to claim 1, wherein the oxide semiconductor field effect transistor is located above the capacitor.

6. The semiconductor structure according to claim 1, wherein the oxide semiconductor field effect transistor is located below the capacitor.

7. The semiconductor structure according to claim 1, wherein the oxide semiconductor field effect transistor is located on one side of the capacitor.

8. The semiconductor structure according to claim 1, wherein the oxide semiconductor field effect transistor comprises:
a first electrode layer located on the substrate;
a first dielectric layer located on the first electrode layer;
a channel layer located on the first dielectric layer and located above the first electrode layer; and
a second electrode layer and a third electrode layer located on the first dielectric layer and located on two sides of the channel layer.

9. The semiconductor structure according to claim 8, wherein a material of the first electrode layer comprises molybdenum, titanium, tantalum, tungsten, aluminum, copper, chromium, or an alloy thereof.

10. The semiconductor structure according to claim 8, wherein a material of the first dielectric layer comprises silicon oxide, silicon nitride, or hafnium nitride.

11. The semiconductor structure according to claim 8, wherein a material of the channel layer comprises an oxide semiconductor, and the oxide semiconductor comprises indium gallium zinc oxide, zinc oxide, indium zinc oxide, cobalt oxide, nickel oxide, strontium copper oxide, copper aluminum oxide, copper indium oxide, or copper gallium oxide.

12. The semiconductor structure according to claim 8, wherein a material of the second electrode layer and a material of the third electrode layer comprise an N-type oxide semiconductor, the N-type oxide semiconductor comprises indium gallium zinc oxide, zinc oxide, or indium zinc oxide, and the N-type oxide semiconductor has an N-type dopant.

13. The semiconductor structure according to claim 8, wherein a material of the second electrode layer and a material of the third electrode layer comprise a P-type oxide semiconductor, and the P-type oxide semiconductor comprises cobalt oxide, nickel oxide, strontium copper oxide, copper aluminum oxide, copper indium oxide, or copper gallium oxide, and the P-type oxide semiconductor has a P-type dopant.

14. The semiconductor structure according to claim 8, wherein the capacitor is located in the substrate and comprises:
a fourth electrode layer located in the substrate;
a fifth electrode layer located on the fourth electrode layer;
a second dielectric layer located between the fourth electrode layer and the substrate; and
a third dielectric layer located between the fourth electrode layer and the fifth electrode layer.

15. The semiconductor structure according to claim 14, wherein the second electrode layer is electrically connected to the fourth electrode layer.

16. The semiconductor structure according to claim 14, wherein the second electrode layer is electrically connected to the fifth electrode layer.

17. The semiconductor structure according to claim 8, further comprising:
a dielectric layer structure located on the substrate, wherein the capacitor and the oxide semiconductor field effect transistor are located in the dielectric layer structure, and the capacitor comprises:
a fourth electrode layer located in the dielectric layer structure;
a fifth electrode layer located on the fourth electrode layer; and
a second dielectric layer located between the fourth electrode layer and the fifth electrode layer.

18. The semiconductor structure according to claim 17, wherein the second electrode layer is electrically connected to the fourth electrode layer.

19. The semiconductor structure according to claim 17, wherein the second electrode layer is electrically connected to the fifth electrode layer.

20. The semiconductor structure according to claim 1, further comprising:
a through-substrate via located in the substrate and passing through the substrate.
